(19) United States
(12) Patent Application Publication
(10) Pub. No.: US 2024/0237200 A1
(43) Pub. Date: Jul. 11, 2024

(54) ASSEMBLY SHEET AND METHOD FOR PRODUCING ASSEMBLY SHEET

(71) Applicant: NITTO DENKO CORPORATION, Osaka (JP)

(72) Inventor: Makoto TSUNEKAWA, Osaka (JP)

(73) Assignee: NITTO DENKO CORPORATION, Osaka (JP)

(21) Appl. No.: 18/557,010

(22) PCT Filed: Jan. 26, 2022
(86) PCT No.: PCT/JP2022/002940

§ 371 Date: Oct. 24, 2023

(30) Foreign Application Priority Data
Apr. 26, 2021 (JP) 2021-074404

(51) Int. Cl. H05K 1/02; H05K 3/24

(52) U.S. Cl. CPC H05K 1/0296; H05K 3/245; H05K 2201/2018; H05K 2203/0228

(57) ABSTRACT

An assembly sheet includes a plurality of wiring circuit boards, a frame, and a reinforcement portion. The wiring circuit board has a support layer, a base insulating layer disposed on a one-surface of the support layer in a thickness direction, and a conductive pattern disposed on a one-surface of the base insulating layer in the thickness direction. The frame supports the wiring circuit board. The reinforcement portion reinforces the frame. The reinforcement portion is disposed on an other-surface of the frame in the thickness direction.

### TECHNICAL FIELD

The present invention relates to an assembly sheet and a method for producing an assembly sheet.

### BACKGROUND ART

Conventionally, an assembly sheet having a plurality of suspension boards with a circuit, a frame body supporting the plurality of suspension boards with a circuit, and a reinforcement portion (reinforcement insulating layer and reinforcement conductive layer) disposed on the frame body has been known (ref: for example, Patent Document 1 below).

### Citation List

### Patent Document

Patent Document 1: Japanese Unexamined Patent Publication No. 2019-153687

### SUMMARY OF THE INVENTION

### Problem to be Solved by the Invention

In the assembly sheet described in Patent Document 1, the reinforcement portion is disposed on the same side as a base insulating layer and a conductive pattern (one side in a thickness direction) with respect to the frame body in the thickness direction. A configuration required for production of a wiring circuit board (for example, dummy wiring and alignment mark) may be disposed on one surface in the thickness direction of the frame body.

Therefore, it is necessary to dispose the reinforcement portion by avoiding the configuration of these, and it is difficult to improve a degree of freedom in arrangement of the reinforcement portion.

The present invention provides an assembly sheet capable of improving a degree of freedom in arrangement of a reinforcement portion, and a method for producing an assembly sheet.

### Means for Solving the Problem

The present invention [1] includes an assembly sheet including a wiring circuit board having a support layer, an insulating layer disposed on one surface of the support layer in a thickness direction, and a conductive pattern disposed on one surface of the insulating layer in the thickness direction; a frame supporting the wiring circuit board; and a reinforcement portion reinforcing the frame, wherein the reinforcement portion is disposed on the other surface of the frame in the thickness direction.

According to such a configuration, the reinforcement portion is disposed on the opposite side (that is, the other side) to the insulating layer and the conductive pattern with respect to the frame in the thickness direction.

Therefore, it is possible to dispose the reinforcement portion by using the other surface of the frame regardless of a presence or absence of the configuration disposed on one surface of the frame.

As a result, it is possible to improve a degree of freedom in arrangement of the reinforcement portion.

The present invention [2] includes the assembly sheet of the above-described [1] further including a second reinforcement portion disposed on one surface of the frame in the thickness direction.

According to such a configuration, it is possible to provide the reinforcement portion on both surfaces of the frame.

As a result, it is possible to further reinforce the frame.

The present invention [3] includes the assembly sheet of the above-described [1] or [2], wherein the frame is made of a metal foil having a thickness of 50 μm or less.

According to such a configuration, when a frame made of a thin metal foil is provided, it is possible to achieve further reinforcement of the frame.

The present invention [4] includes the assembly sheet of the above-described [3], wherein when a thickness of the frame is 100%, the thickness of the reinforcement portion is 50% or more and 300% or less.

The present invention [5] includes a method for producing an assembly sheet, the assembly sheet of any one of the above-described [1] to [4], including a patterning step of forming an insulating layer and a conductive pattern on one surface of a metal foil drawn from a first roll as a roll of the metal foil and forming a reinforcement portion on the other surface of the metal foil to produce a second roll having the plurality of assembly sheets, and a cutting step of cutting each of the plurality of assembly sheets from the second roll.

According to such a configuration, it is possible to form the reinforcement portion in a state where the metal foil is stretched between the first roll and the second roll.

Therefore, it is possible to suppress the occurrence of wrinkles in the assembly sheet by the reinforcement portion when the cut assembly sheet is handled.

As a result, it is possible to improve handleability of the cut assembly sheet.

The present invention [6] includes the method for producing an assembly sheet of the above-described [5] further including a plating step of plating a terminal of the conductive pattern of the cut assembly sheet.

According to such a configuration, it is possible to suppress the occurrence of the wrinkles in the assembly sheet during the plating step.

### Effect of the Invention

According to the assembly sheet and the method for producing an assembly sheet of the present invention, it is possible to improve a degree of freedom in arrangement of a reinforcement portion.

### BRIEF DESCRIPTION OF THE DRAWINGS

FIG. 1 shows a plan view of an assembly sheet as one embodiment of the present invention.

FIG. 2A shows an A-A cross-sectional view of the assembly sheet shown in FIG. 1.

FIG. 2B shows a B-B cross-sectional view of the assembly sheet shown in FIG. 1.

FIGS. 3A to 3D show explanatory views for illustrating a patterning step of a method for producing the assembly sheet shown in FIG. 1;

FIG. 3A illustrating a step of forming a base insulating layer on a metal foil,

FIG. 3B illustrating a step of forming a wiring on the base insulating layer, and forming a reinforcement portion on the metal foil,

FIG. 3C illustrating a step of forming a cover insulating layer on the wiring and the base insulating layer, and

FIG. 3D illustrating a step of etching the metal foil and forming a cut-out between a frame and a wiring circuit board.

FIG. 4A, subsequent to FIG. 3D, shows an explanatory view for illustrating a cutting step of the method for producing an assembly sheet.

FIG. 4B, subsequent to FIG. 4A, shows an explanatory view for illustrating a plating step of the method for producing an assembly sheet.

FIG. 5 shows an explanatory view for illustrating a first modified example.

FIG. 6 shows an explanatory view for illustrating a second modified example.

FIG. 7 shows an explanatory view for illustrating a third modified example.

FIG. 8 shows an explanatory view for illustrating a fourth modified example.

FIG. 9 shows an explanatory view for illustrating a fifth modified example.

FIG. 10 shows an explanatory view for illustrating a sixth modified example.

FIG. 11 shows an explanatory view for illustrating a seventh modified example.

FIG. 12 shows an explanatory view for illustrating an eighth modified example.

### DESCRIPTION OF EMBODIMENTS

### 1. Assembly Sheet

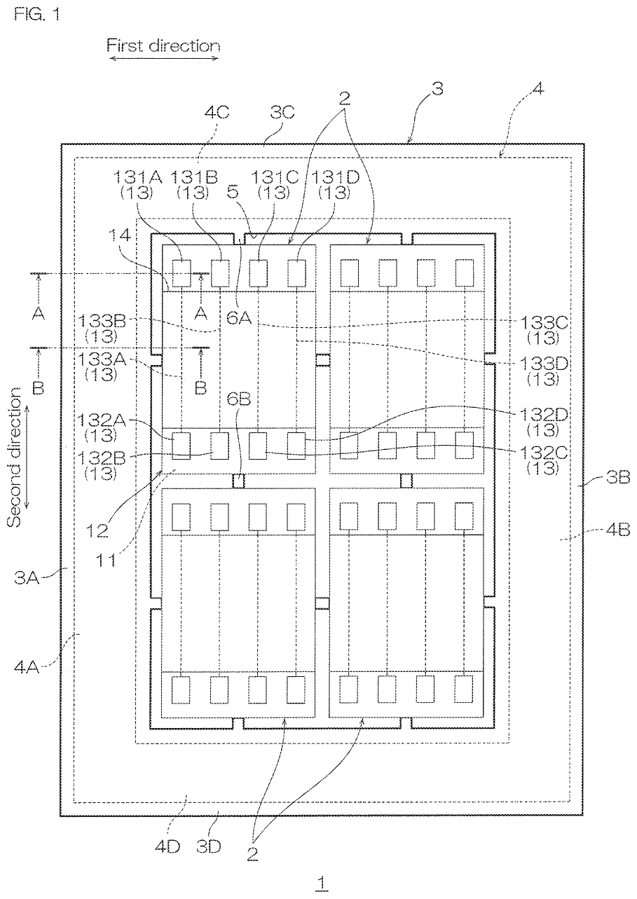

As shown in FIG. 1, an assembly sheet 1 has a sheet shape extending in a first direction and a second direction. The second direction is perpendicular to the first direction. The assembly sheet 1 includes a plurality of wiring circuit boards 2, a frame 3, and a reinforcement portion 4.

### (1) Wiring Circuit Board

The plurality of wiring circuit boards 2 are disposed spaced from each other in the second direction, while disposed spaced from each other in the first direction. Each of the plurality of wiring circuit boards 2 has the same structure. Therefore, one of the wiring circuit boards 2 of the plurality of wiring circuit boards 2 is described, and descriptions of the other wiring circuit boards 2 are omitted.

The wiring circuit board 2 extends in the first direction and the second direction. In this embodiment, the wiring circuit board 2 has a generally rectangular shape. A shape of the wiring circuit board 2 is not limited.

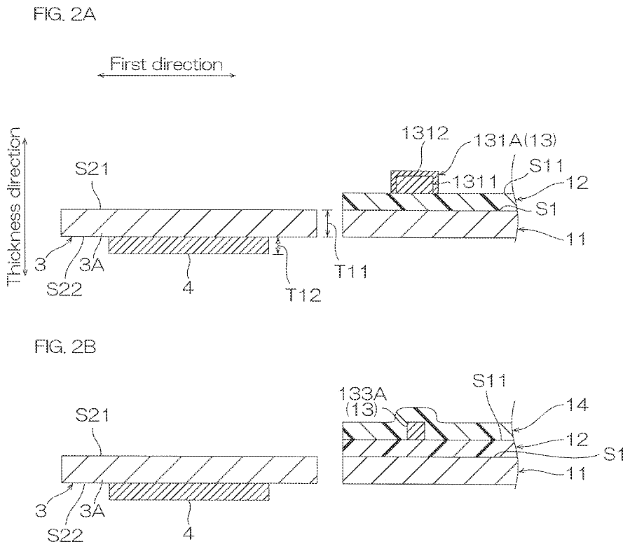

As shown in FIG. 2A, the wiring circuit board 2 has a support layer 11, a base insulating layer 12 as one example of an insulating layer, a conductive pattern 13, and a cover insulating layer 14.

### (1-1) Support Layer

The support layer 11 supports the base insulating layer 12, the conductive pattern 13, and the cover insulating layer 14. In this embodiment, the support layer 11 is made of a metal foil. Examples of a metal include stainless steel and copper alloys.

A thickness of the metal foil, that is, the thickness of the support layer 11 is, for example, 50 μm or less, preferably 30 μm or less, and for example, 10 μm or more, preferably 15 μm or more.

### (1-2) Base Insulating Layer

The base insulating layer 12 is disposed on a one-surface S1 of the support layer 11 in a thickness direction. The thickness direction is perpendicular to the first direction and the second direction. The base insulating layer 12 is disposed between the support layer 11 and the conductive pattern 13 in the thickness direction. The base insulating layer 12 insulates the support layer 11 from the conductive pattern 13. The base insulating layer 12 is made of a resin. An example of the resin includes polyimide.

The thickness of the base insulating layer 12 is, for example, 30 μm or less, preferably 15 μm or less, and for example, 1 μm or more, preferably 3 μm or more.

### (1-3) Conductive Pattern

The conductive pattern 13 is disposed on a one-surface S11 of the base insulating layer 12 in the thickness direction. The conductive pattern 13 is disposed on the opposite side to the support layer 11 with respect to the base insulating layer 12 in the thickness direction. The conductive pattern 13 is made of a metal. An example of the metal includes copper. A shape of the conductive pattern 13 is not limited.

In this embodiment, as shown in FIG. 1, the conductive pattern 13 has a plurality of terminals 131A, 131B, 131C, and 131D; a plurality of terminals 132A, 132B, 132C, and 132D; and a plurality of wirings 133A, 133B, 133C, and 133D. The number of terminals and the number of wirings are not limited.

### (1-3-1) Terminal

The terminals 131A, 131B, 131C, and 131D are disposed in one end portion of the wiring circuit board 2 in the second direction. In this embodiment, the terminals 131A, 131B, 131C, and 131D are disposed spaced from each other in the first direction. Each of the terminals 131A, 131B, 131C, and 131D has a square land shape.

As shown in FIG. 2A, the terminal 131A has a conductive layer 1311 and a plating layer 1312.

The conductive layer 1311 is a main body portion of the terminal 131A. The conductive layer 1311 is disposed on the one-surface S11 of the base insulating layer 12 in the thickness direction.

The thickness of the conductive layer 1311 is, for example, 3 μm or more, preferably 5 μm or more, and for example, 50 μm or less, preferably 30 μm or less.

The plating layer 1312 covers the surface of the conductive layer 1311. The plating layer 1312 suppresses corrosion of the conductive layer 1311. The plating layer 1312 is made of the metal. Examples of the metal include nickel, gold, and tin. The plating layer 1312 may consist of one layer or may consist of a plurality of layers. When the plating layer 1312 consists of the plurality of layers, each of the plurality of layers may be made of metals different from each other.

The thickness of the plating layer 1312 is, for example, 0.1 μm or more, preferably 0.2 μm or more, and for example, 5 μm or less, preferably 4 μm or less.

The terminals 131B, 131C, and 131D have the same structure as the terminal 131A. Therefore, the descriptions of the terminals 131B, 131C, and 131D are omitted.

As shown in FIG. 1, the terminals 132A, 132B, 132C, and 132D are disposed in the other end portion of the wiring circuit board 2 in the second direction. In this embodiment, the terminals 132A, 132B, 132C, and 132D are disposed spaced from each other in the first direction. Each of the terminals 132A, 132B, 132C, and 132D has a square land shape.

The terminals 132A, 132B, 132C, and 132D have the same structure as the terminal 131A. Therefore, the descriptions of the terminals 132A, 132B, 132C, and 132D are omitted.

### (1-3-2) Wiring

One end of the wiring 133A is connected to the terminal 131A. The other end of the wiring 133A is connected to the terminal 132A. The wiring 133A electrically connects the terminal 131A to the terminal 132A.

One end of the wiring 133B is connected to the terminal 131B. The other end of the wiring 133B is connected to the terminal 132B. The wiring 133B electrically connects the terminal 131B to the terminal 132B.

One end of the wiring 133C is connected to the terminal 131C. The other end of the wiring 133C is connected to the terminal 132C. The wiring 133C electrically connects the terminal 131C to the terminal 132C.

One end of the wiring 133D is connected to the terminal 131D. The other end of the wiring 133D is connected to the terminal 132D. The wiring 133D electrically connects the terminal 131D to the terminal 132D.

In the following descriptions, each of the plurality of terminals 131A, 131B, 131C, and 131D is referred to as a terminal 131; each of the plurality of terminals 132A, 132B, 132C, and 132D is referred to as a terminal 132; and each of the plurality of wirings 133A, 133B, 133C, and 133D is referred to as a wiring 133.

The wiring 133 is made of the same metal as the conductive layer 1311 of the terminal 131. The thickness of the wiring 133 is, for example, 3 μm or more, preferably 5 μm or more, and for example, 50 μm or less, preferably 30 μm or less.

### (1-4) Cover Insulating Layer

As shown in FIG. 1, the cover insulating layer 14 covers all of the wirings 133. The cover insulating layer 14 is disposed on the base insulating layer 12 in the thickness direction. The cover insulating layer 14 does not cover the terminals 131 and the terminals 132. The cover insulating layer 14 is made of the resin. An example of the resin includes polyimide.

The thickness of the cover insulating layer 14 is, for example, 30 μm or less, preferably 15 μm or less, and for example, 1 μm or more, preferably 3 μm or more.

### (2) Frame

The frame 3 is disposed on the outer periphery of the assembly sheet 1. The frame 3 surrounds the plurality of wiring circuit boards 2. In this embodiment, the frame 3 has a frame shape. Specifically, the frame 3 has a first frame 3A, a second frame 3B, a third frame 3C, and a fourth frame 3D.

The first frame 3A is disposed in one end portion of the assembly sheet 1 in the first direction. The first frame 3A extends in the second direction.

The second frame 3B is disposed in the other end portion of the assembly sheet 1 in the first direction. The second frame 3B is disposed away from the first frame 3A in the first direction. The plurality of wiring circuit boards 2 are disposed between the first frame 3A and the second frame 3B in the first direction. The second frame 3B extends in the second direction.

The third frame 3C is disposed in one end portion of the assembly sheet 1 in the second direction. The third frame 3C extends in the first direction. One end portion of the third frame 3C in the first direction is connected to one end portion of the first frame 3A in the second direction. The other end portion of the third frame 3C in the first direction is connected to one end portion of the second frame 3B in the second direction.

The fourth frame 3D is disposed in the other end portion of the assembly sheet 1 in the second direction. The fourth frame 3D is disposed away from the third frame 3C in the second direction. The plurality of wiring circuit boards 2 are disposed between the third frame 3C and the fourth frame 3D in the second direction. The fourth frame 3D extends in the first direction. One end portion of the fourth frame 3D in the first direction is connected to the other end portion of the first frame 3A in the second direction. The other end portion of the fourth frame 3D in the first direction is connected to the other end portion of the second frame 3B in the second direction.

As shown in FIG. 2A, the frame 3 is made of the metal foil. The frame 3 is made of the same metal foil as the support layer 11 of the wiring circuit board 2. Examples of the metal include stainless steel and copper alloys. The thickness of the metal foil, that is, a thickness T11 of the frame 3 is, for example, 50 μm or less, preferably 30 μm or less, and for example, 10 μm or more, preferably 15 μm or more.

Since the thickness of the metal foil is the above-described upper limit value or less, rigidity of the frame 3 is low. Therefore, when the assembly sheet 1 is handled, there is a possibility that wrinkles occur in the assembly sheet 1. Therefore, handling of the assembly sheet 1 is difficult.

Examples of a case of the difficult handling of the assembly sheet 1 include a case of carrying the assembly sheet 1, and a plating step in the method for producing the assembly sheet 1 to be described later.

Further, in this embodiment, the assembly sheet 1 has a cut-out 5 between the frame 3 and the wiring circuit board 2, and the two wiring circuit boards 2. Therefore, the rigidity of the entire assembly sheet 1 is further low. Therefore, the handling of the assembly sheet 1 is more difficult.

The assembly sheet 1 has a connecting portion 6A which connects the frame 3 to the wiring circuit board 2, and a connecting portion 6B which connects the two wiring circuit boards 2 to each other. The plurality of wiring circuit boards 2 are supported by the frame 3 via the connecting portion 6A, while being connected to each other via the connecting portion 6B.

### (3) Reinforcement Portion

As shown in FIG. 2A, the reinforcement portion 4 is disposed on an other-surface S22 of the frame 3 in the thickness direction. As shown in FIG. 1, in this embodiment, the reinforcement portion 4 has a frame shape. Specifically, the reinforcement portion 4 has a first reinforcement portion 4A, a second reinforcement portion 4B, a third reinforcement portion 4C, and a fourth reinforcement portion 4D.

The first reinforcement portion 4A is disposed on the other-surface S22 of the first frame 3A. The first reinforcement portion 4A reinforces the first frame 3A. The first reinforcement portion 4A extends in the second direction. In other words, the first reinforcement portion 4A extends in a direction in which the first frame 3A extends.

The second reinforcement portion 4B is disposed on the other-surface S22 of the second frame 3B. The second reinforcement portion 4B reinforces the second frame 3B. The second reinforcement portion 4B extends in the second direction. In other words, the second reinforcement portion 4B extends in a direction in which the second frame 3B extends.

The third reinforcement portion 4C is disposed on the other-surface S22 of the third frame 3C. The third reinforcement portion 4C reinforces the third frame 3C. The third reinforcement portion 4C extends in the first direction. In other words, the third reinforcement portion 4C extends in a direction in which the third frame 3C extends. One end portion of the third reinforcement portion 4C in the first direction is connected to one end portion of the first reinforcement portion 4A in the second direction. The other end portion of the third reinforcement portion 4C in the first direction is connected to one end portion of the second reinforcement portion 4B in the second direction.

The fourth reinforcement portion 4D is disposed on the other-surface S22 of the fourth frame 3D. The fourth reinforcement portion 4D reinforces the fourth frame 3D. The fourth reinforcement portion 4D extends in the first direction. In other words, the fourth reinforcement portion 4D extends in a direction in which the fourth frame 3D extends. One end portion of the fourth reinforcement portion 4D in the first direction is connected to the other end portion of the first reinforcement portion 4A in the second direction. The other end portion of the fourth reinforcement portion 4D in the first direction is connected to the other end portion of the second reinforcement portion 4B in the second direction.

As shown in FIG. 2A, in this embodiment, the reinforcement portion 4 is made of the metal. The reinforcement portion 4 is preferably made of the same metal as the wiring 133 of the wiring circuit board 2. When the reinforcement portion 4 and the wiring 133 are the same metal, it is possible to form the reinforcement portion 4 by using a step of forming the wiring 133.

The thickness of the reinforcement portion 4 is, for example, 3 μm or more, preferably 5 μm or more, and for example, 50 μm or less, preferably 30 μm or less.

When the thickness T11 of the frame 3 is 100%, a thickness T12 of the reinforcement portion 4 is, for example, 50% or more. preferably 80% or more, more preferably 100% or more. further more preferably 110% or more, and for example, 300% or less, preferably 250% or less, more preferably 200% or less.

When the thickness T12 of the reinforcement portion 4 in a case where the thickness T11 of the frame 3 is 100% is the above-described lower limit value or more, it is possible to further improve the strength of the frame 3. When the thickness T12 of the reinforcement portion 4 in a case where the thickness T11 of the frame 3 is 100% is the above-described upper limit value or less, it is possible to form the reinforcement portion 4 by using a step of forming the conductive pattern 13.

The total sum of the thickness T11 of the frame 3 and the thickness T12 of the reinforcement portion 4 is, for example, 16 μm or more, preferably 25 μm or more, more preferably 50 μm or more, and for example, 200 μm or less, preferably 150 μm or less.

### 2. Method for Producing Assembly Sheet

Next, a method for producing the above-described assembly sheet 1 is described.

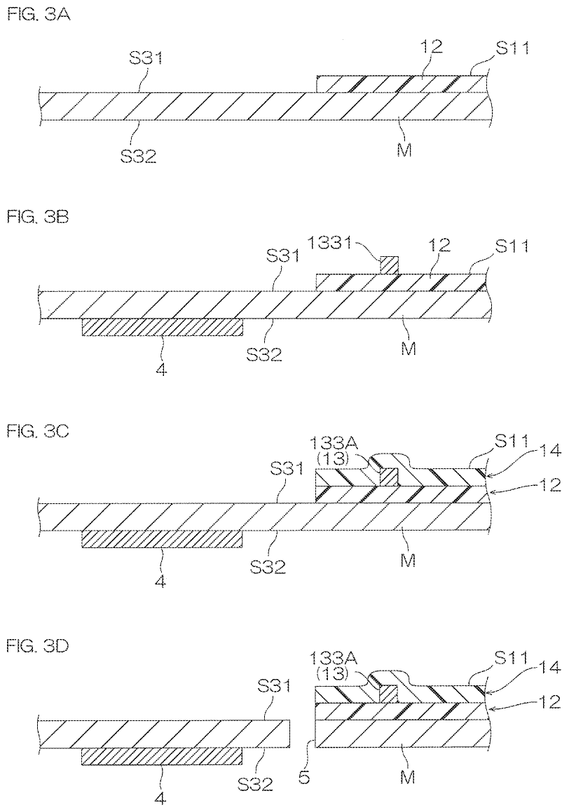

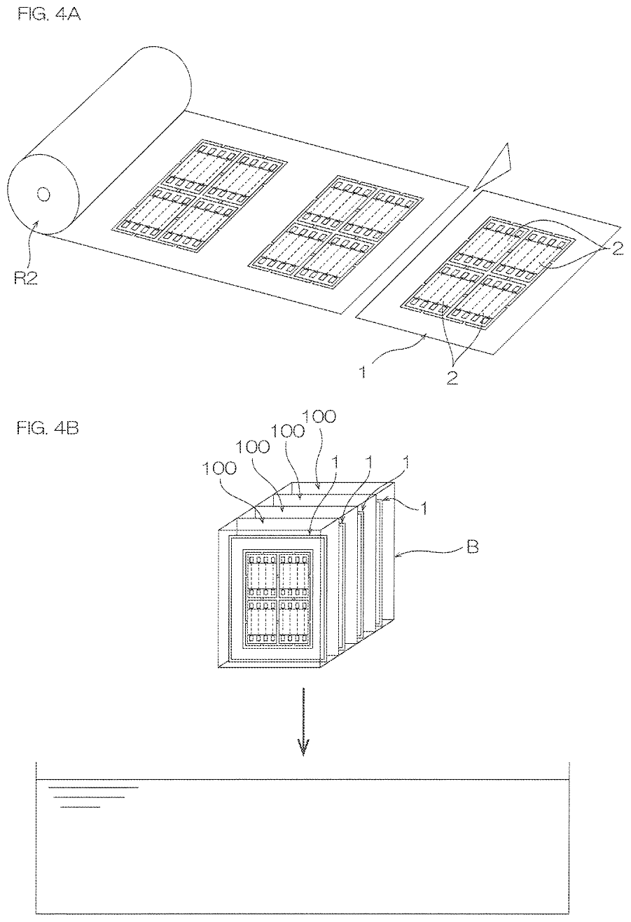

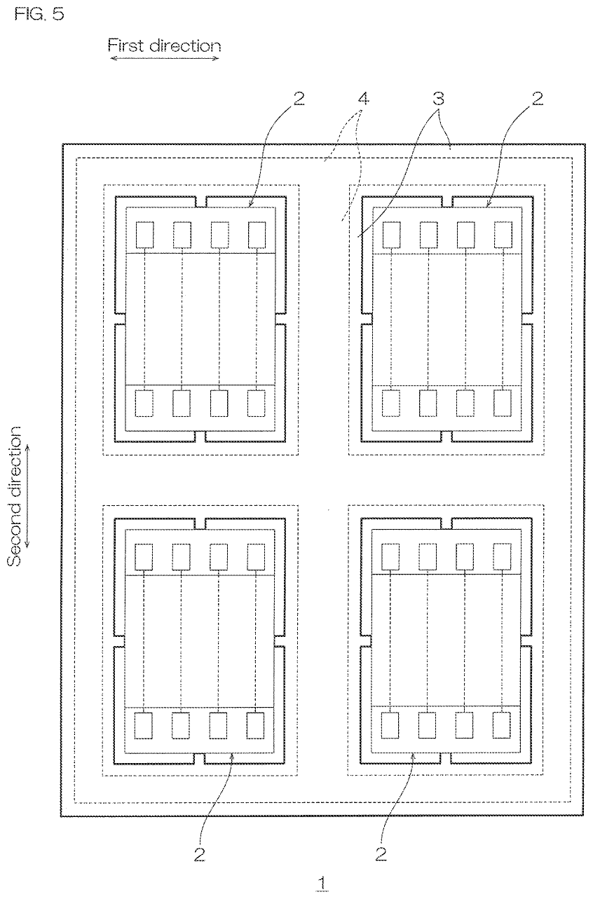

In this embodiment, the assembly sheet 1 is produced by a semi-additive method. The assembly sheet 1 may be also produced by an additive method. The method for producing the assembly sheet 1 includes a patterning step (ref: FIGS. 3A to 3D), a cutting step (ref: FIG. 4A), and a plating step (ref: FIG. 4B).

### (1) Patterning Step

As shown in FIGS. 3A to 3D, in the patterning step, the base insulating layer 12 (ref: FIG. 3A) and the conductive pattern 13 (ref: FIG. 3B) are formed on a one-surface S31 of a metal foil M drawn from a first roll R1 (not shown) which is a roll of the metal foil, and the reinforcement portion 4 (ref: FIG. 3B) is formed on an other-surface S32 of the metal foil M to produce a second roll R2 (ref: FIG. 4A) having the plurality of assembly sheets 1. The metal foil M is stretched between the first roll R1 and the second roll R2 during the pattering step.

Specifically, in order to form the base insulating layer 12, first, a solution (varnish) of a photosensitive resin is coated on the one-surface S31 of the metal foil M and dried to form a coating film of the photosensitive resin. Next, the coating film of the photosensitive resin is exposed to light and developed.

Thus, as shown in FIG. 3A, the base insulating layer 12 is formed on the one-surface S31 of the metal foil M.

The conductive pattern 13 and the reinforcement portion 4 are formed by electrolytic plating.

In order to form the conductive pattern 13 and the reinforcement portion 4 by the electrolytic plating, first, a seed layer is formed on the one-surface S11 of the base insulating layer 12, the one-surface S31 of the metal foil M, and the other-surface S32 of the metal foil M. The seed layer is, for example, formed by sputtering. Examples of a material for the seed layer include chromium, copper, nickel, titanium, and alloys of these.

Next, a first plating resist is attached onto the one-surface S11 of the base insulating layer 12 and the one-surface S31 of the metal foil M, and a second plating resist is attached onto the other-surface S32 of the metal foil M.

Next, the first plating resist is exposed to light, while portions where the conductive layer 1311 (ref: FIG. 2A) and the wiring 133 (ref: FIG. 2A) are formed are shielded, and the second plating resist is exposed to light, while a portion where the reinforcement portion 4 (ref: FIG. 2A) is formed is shielded.

Next, the first plating resist and the second plating resist which are exposed to light are developed. Then, the first plating resist and the second plating resist of the shielded portion are removed, and the seed layer is exposed to the portions where the conductive layer 1311, the wiring 133, and the reinforcement portion 4 are formed. The first plating resist and the second plating resist of the exposed portions, that is, the portions where the conductive layer 1311, the wiring 133, and the reinforcement portion 4 are not formed remain.

Next, the conductive layer 1311, the wiring 133, and the reinforcement portion 4 are formed on the exposed seed layer by the electrolytic plating. After the electrolytic plating is completed, the first plating resist and the second plating resist are peeled. Thereafter, the seed layer exposed by peeling the first plating resist and the second plating resist is removed by etching.

Thus, as shown in FIG. 3B, the conductive layer 1311 and the wiring 133 are formed on the one-surface S11 of the base insulating layer 12, and the reinforcement portion 4 is formed on the other-surface S32 of the metal foil M.

Next, as shown in FIG. 3C, the cover insulating layer 14 is formed on the base insulating layer 12 and the conductive pattern 13 in the same manner as the formation of the base insulating layer 12.

Next, as shown in FIG. 3D, the metal foil M is etched to form the cut-out 5 between the frame 3 and the wiring circuit board 2, and between the two wiring circuit boards 2.

As described above, the second roll R2 having the plurality of assembly sheets 1 is produced.

### (2) Cutting Step

Next, after the patterning step, the cutting step is carried out.

As shown in FIG. 4A, in the cutting step, each of the plurality of assembly sheets 1 is cut from the second roll R2. Specifically, the assembly sheet 1 which is fed out from the second roll R2 is cut out with a cutter. A method for cutting is not limited. Thus, the plurality of assembly sheets 1 which are independent of each other are obtained.

### (3) Plating Step

Next, after the cutting step, the plating step is carried out.

In the plating step, the conductive layers 1311 of all of the terminals 131 and the conductive layers 1311 of all of the terminals 132 of the cut assembly sheet 1 are plated. In the plating step, the conductive layer 1311 is plated by electroless plating. Thus, the plating layer 1312 (ref: FIG. 2A) is formed on the surface of the conductive layer 1311.

Specifically, as shown in FIG. 4B, the cut assembly sheet 1 is placed in a basket B, and is immersed together with the basket B in a plating solution. The basket B has a plurality of housing portions 100. Each of the plurality of housing portions 100 is divided from each other. The one housing portion 100 houses the one assembly sheet 1.

At this time, the frame 3 of the cut assembly sheet 1 is reinforced by the reinforcement portion 4. Therefore, it is possible to suppress the occurrence of the wrinkles in the assembly sheet 1 during the plating step.

### 3. Function and Effect

(1) According to the assembly sheet 1, as shown in FIG. 2A, the reinforcement portion 4 is disposed on the opposite side (that is, the other side) to the base insulating layer 12 and the conductive pattern 13 with respect to the frame 3 in the thickness direction.

Therefore, it is possible to dispose the reinforcement portion 4 by using the other-surface S22 of the frame 3 regardless of a presence or absence of the configuration disposed on the one-surface S21 of the frame 3.

As a result, it is possible to improve a degree of freedom in arrangement of the reinforcement portion 4.

(2) According to the assembly sheet 1, the frame 3 is made of a metal foil having a thickness of 50 μm or less.

Thus, according to the assembly sheet 1, when the frame 3 made of a thin metal foil is provided, it is possible to achieve reinforcement of the frame 3.

(3) According to the method for producing the assembly sheet 1, as shown in FIG. 3B, it is possible to form the reinforcement portion 4 in a state where the metal foil M is stretched between the first roll R1 and the second roll R2.

Therefore, as shown in FIG. 4A, it is possible to suppress the occurrence of the wrinkles in the assembly sheet 1 by the reinforcement portion 4 when the cut assembly sheet 1 is handled.

As a result, it is possible to improve handleability of the cut assembly sheet 1.

(4) According to the method for producing the assembly sheet 1, as shown in FIG. 4B, the terminal 131 and the terminal 132 of the cut assembly sheet 1 are plated during the plating step.

Then, the frame 3 of the cut assembly sheet 1 is reinforced by the reinforcement portion.

Therefore, it is possible to suppress the occurrence of the wrinkles in the assembly sheet 1 during the plating step.

### 4. Modified Examples

Next, modified examples are described with reference to FIGS. 5 to 12. In each modified example, the same reference numerals are provided for members corresponding to each of those in the above-described embodiment, and their detailed description is omitted.

(1) As shown in FIG. 5, the frame 3 may be also between the two wiring circuit boards 2. In this case, the reinforcement portion 4 may be also provided on the other-surface S22 of the frame 3 between the two wiring circuit boards 2.

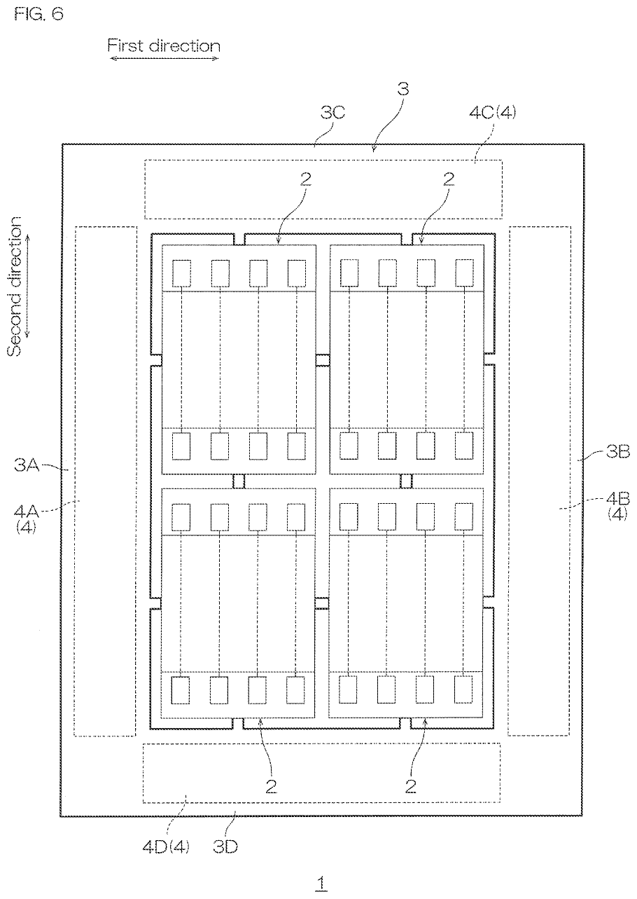

(2) As shown in FIG. 6, each of the first reinforcement portion 4A, the second reinforcement portion 4B, the third reinforcement portion 4C, and the fourth reinforcement portion 4D may be also away from each other.

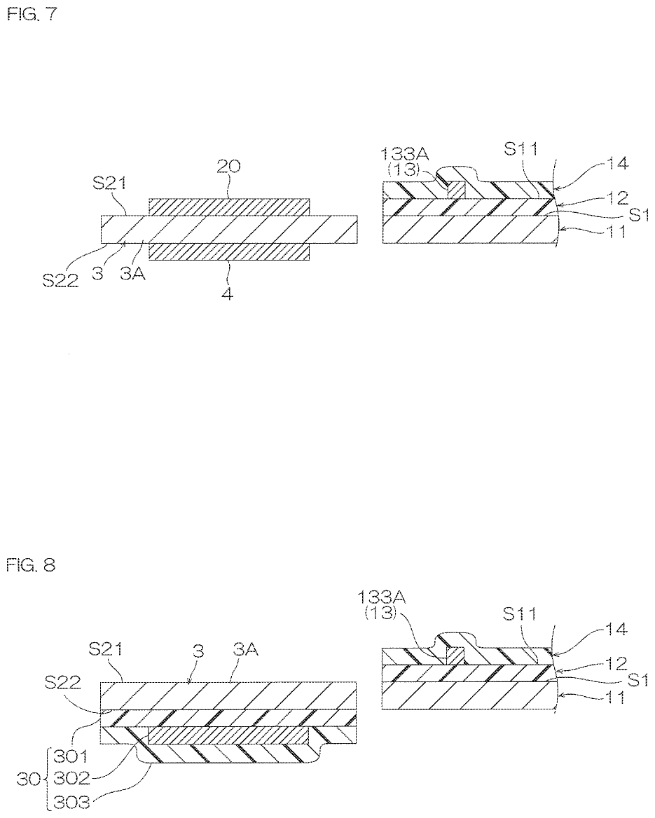

(3) As shown in FIG. 7, the assembly sheet 1 may also include the reinforcement portion 4 disposed on the other-surface S22 of the frame 3 in the thickness direction, and a second reinforcement portion 20 disposed on the one-surface S21 of the frame 3 in the thickness direction. The second reinforcement portion 20 may be also made of the same metal as the reinforcement portion 4.

According to such a configuration, it is possible to provide the reinforcement portions (the reinforcement portion 4 and the second reinforcement portion 20) on both surfaces of the frame 3.

As a result, it is possible to further reinforce the frame 3.

(4) As shown in FIG. 8, a reinforcement portion 30 may also have a first layer 301 made of the same resin as the base insulating layer 12, and a second layer 302 made of the same metal as the wiring 133. The first layer 301 is disposed on the other-surface S22 of the frame 3. The second layer 302 is disposed on the first layer 301.

Further, the reinforcement portion 30 may also have a third layer 303 made of the same resin as the cover insulating layer 14. The third layer 303 is disposed on the second layer 302.

(5) As shown in FIG. 9, a reinforcement portion 40 may also have a first layer 401 made of the metal and a second layer 402 made of the metal.

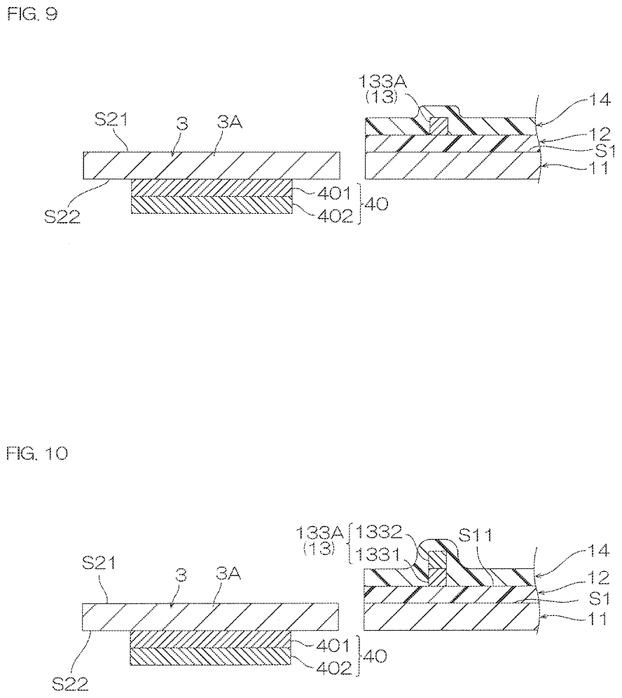

(6) As shown in FIG. 10, the wiring 133 may also have the first conductive layer 1331 and the second conductive layer 1332. The first conductive layer 1331 is disposed on the one-surface S11 of the base insulating layer 12 in the thickness direction. The first conductive layer 1331 may be also made of the same metal as the conductive layer 1311 of the terminal 131. The second conductive layer 1332 is disposed on the first conductive layer 1331 in the thickness direction. At least a portion of the second conductive layer 1332 is in contact with the first conductive layer 1331. In other words, the second conductive layer 1332 is electrically connected to the first conductive layer 1331.

In this case, the first layer 401 of the reinforcement portion 40 described above may be also made of the same metal as the first conductive layer 1331. The second layer 402 may be also made of the same metal as the second conductive layer 1332.

According to such a configuration, it is possible to form the reinforcement portion 40 by using a step of forming the first conductive layer 1331 and a step of forming the second conductive layer 1332.

Therefore, it is possible to improve a degree of freedom in design of the conductive pattern 13, and to form the reinforcement portion 40, while suppressing an increase in the number of steps.

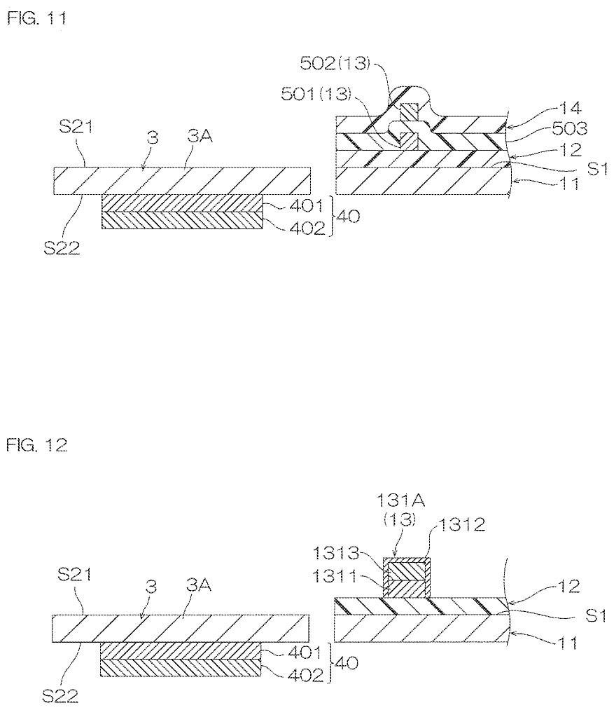

(7) As shown in FIG. 11, the conductive pattern 13 may also have a first wiring 501, a second wiring 502, and an intermediate insulating layer 503.

The first wiring 501 is disposed on the base insulating layer 12. The first wiring 501 is formed by the electrolytic plating in the same manner as the above-described wiring 133.

The second wiring 502 is disposed away from the first wiring 501. In other words, the second wiring 502 is not electrically conducted to the first wiring 501. The second wiring 502 is disposed on the intermediate insulating layer 503. The second wiring 502 is formed by the electrolytic plating in the same manner as the above-described wiring 133.

The intermediate insulating layer 503 is disposed between the first wiring 501 and the second wiring 502. The intermediate insulating layer 503 insulates the first wiring 501 from the second wiring 502. The intermediate insulating layer 503 is formed on the first wiring 501 and the base insulating layer 12 in the same manner as the base insulating layer 12.

In this case, the first layer 401 of the reinforcement portion 40 described above may be also made of the same metal as the first wiring 501. The second layer 402 may be also made of the same metal as the second wiring 502.

According to such a configuration, it is possible to form the reinforcement portion 40 by using a step of forming the first wiring 501 and a step of forming the second wiring 502.

Therefore, it is possible to improve the degree of freedom in the design of the conductive pattern 13, and to form the reinforcement portion 40, while suppressing an increase in the number of steps.

(8) As shown in FIG. 12, the terminal 131 or the terminal 132 may also further have a second conductive layer 1313 disposed on the conductive layer 1311.

In this case, the first layer 401 of the reinforcement portion 40 described above may be also made of the same metal as the conductive layer 1311. The second layer 402 may be also made of the same metal as the second conductive layer 1313.

(9) The above-described embodiment and each modified example can be used in combination.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

The assembly sheet of the present invention and the method for producing an assembly sheet of the present invention are used in production of a wiring circuit board.

### Description Of Reference Numerals

1 Assembly sheet
2 Wiring circuit board
3 Frame
S21 One surface of frame
S22 Other surface of frame
4 Reinforcement portion
41 First layer
42 Second layer
11 Support layer
S1 One surface of support layer
12 Base insulating layer
S11 One surface of base insulating layer
13 Conductive pattern
131A Terminal
133A Wiring
M Metal foil
R1 First roll
R2 Second roll
20 Second reinforcement portion

1. An assembly sheet comprising:
a wiring circuit board having a support layer, an insulating layer disposed on one surface of the support layer in a thickness direction, and a conductive pattern disposed on one surface of the insulating layer in the thickness direction;
a frame supporting the wiring circuit board; and
a reinforcement portion reinforcing the frame, wherein
the reinforcement portion is disposed on the other surface of the frame in the thickness direction.

2. The assembly sheet according to claim 1 further comprising:
a second reinforcement portion disposed on one surface of the frame in the thickness direction.

3. The assembly sheet according to claim 1, wherein the frame is made of a metal foil having a thickness of 50 μm or less.

4. The assembly sheet according to claim 3, wherein
when a thickness of the frame is 100%, the thickness of the reinforcement portion is 50% or more and 300% or less.

5. A method for producing an assembly sheet, the assembly sheet according to claim 1, comprising:
a patterning step of forming an insulating layer and a conductive pattern on one surface of a metal foil drawn from a first roll as a roll of the metal foil and forming a reinforcement portion on the other surface of the metal foil to produce a second roll having the plurality of assembly sheets, and
a cutting step of cutting each of the plurality of assembly sheets from the second roll.

6. The method for producing an assembly sheet according to claim 5 further comprising:
a plating step of plating a terminal of the conductive pattern of the cut assembly sheet.
